(19) United States
(12) Patent Application Publication
(10) Pub. No.: US 2019/0056874 A1
(43) Pub. Date: Feb. 21, 2019

(54) SYSTEM AND METHOD FOR PRESERVING DATA IN VOLATILE MEMORY

(71) Applicant: NANYA TECHNOLOGY CORPORATION, New Taipei city (TW)

(72) Inventors: Chung-Hsun LEE, New Taipei City (TW); Hsien-Wen LIU, Taoyuan City (TW)

(21) Appl. No.: 15/679,148

(22) Filed: Aug. 16, 2017

(51) Int. Cl. G06F 3/06; G11C 11/406

(52) U.S. Cl. CPC G06F 3/0619; G06F 3/0647; G11C 11/406; G06F 3/0673; G06F 3/0652

(57) ABSTRACT

Present disclosure relates to a system for preserving data in a volatile memory and a method thereof. The volatile memory comprises a plurality of word lines for storing data. The system comprises an accessing detector. The accessing detector is configured to detect a row-hammer indication indicating a first word line is frequently accessed, wherein the accessing detector is configured to copy data stored in the first word line to a second word line when the row-hammer indication is detected on the first word line, wherein the data stored in the first and the second word lines are available to be selectively accessed.

### BACKGROUND

### Field of Invention

Present disclosure relates to a system and a method for preserving data in volatile memory.

### Description of Related Art

Repeatedly accessing a single row in a memory may cause some side effects. Row hammer effect, or also known as one row disturb, happens when a row is frequently accessed within a refresh window of the memory cell it belongs to. It is highly possible that data stored in the rows adjacent to the row being frequently accessed may be corrupted due to the row hammer effect. Some solutions are applied to prevent such a failure, such as limiting access times to the row in one refresh cycle or increasing the refresh rate of the memory cell. However, the solutions may cause some other problems, therefore, alternatives are required.

### SUMMARY

Present disclosure relates to a system for preserving data in a volatile memory, wherein the volatile memory comprises a plurality of word lines for storing data. The system comprises an accessing detector. The accessing detector is configured to detect a row-hammer indication indicating a first word line is frequently accessed, wherein the row-hammer indication triggers the accessing detector to copy data stored in the first word line to a second word line, wherein the data stored in the first and the second word lines are available to be selectively accessed.

Another aspect of present disclosure is to provide a method for preserving data in a volatile memory. The volatile memory comprises a plurality of word lines for storing data. The method comprises following steps: detecting, by an accessing detector, a row-hammer indication indicating a first word line is frequently accessed; copying, by the accessing detector, data stored in the first word line to a second word line, wherein the data stored in the first and the second word lines are available to be selectively accessed.

It is to be understood that both the foregoing general description and the following detailed description are by examples, and are intended to provide further explanation of the disclosure as claimed.

### BRIEF DESCRIPTION OF THE DRAWINGS

Present disclosure can be more fully understood by reading the following detailed description of the embodiment, with reference made to the accompanying drawings as follows:

FIG. 1 is a schematic diagram of a system for preserving data in a volatile memory according to some embodiments of present disclosure;

FIG. 2 is a schematic diagram of a system for preserving data in a volatile memory according to the embodiment of FIG. 1; and

FIG. 3 is a flow chart of a method for preserving data in a volatile memory according to some embodiments of present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

As used herein, the terms “comprising,” “including,” “having,” and the like are to be understood to be open-ended, i.e., to mean including but not limited to.

Reference throughout the specification to “one embodiment” or “an embodiment” means that a particular feature, structure, implementation, or characteristic described in connection with the embodiment is included in at least one embodiment of the present disclosure. Thus, uses of the phrases “in one embodiment” or “in an embodiment” in various places throughout the specification are not necessarily all referring to the same embodiment. Furthermore, the particular features, structures, implementation, or characteristics may be combined in any suitable manner in one or more embodiments.

In the following description and claims, the terms “coupled” and “connected”, along with their derivatives, may be used. In particular embodiments, “connected” and “coupled” may be used to indicate that two or more elements are in direct physical or electrical contact with each other, or may also mean that two or more elements may be in indirect contact with each other. “Coupled” and “connected” may still be used to indicate that two or more elements cooperate or interact with each other.

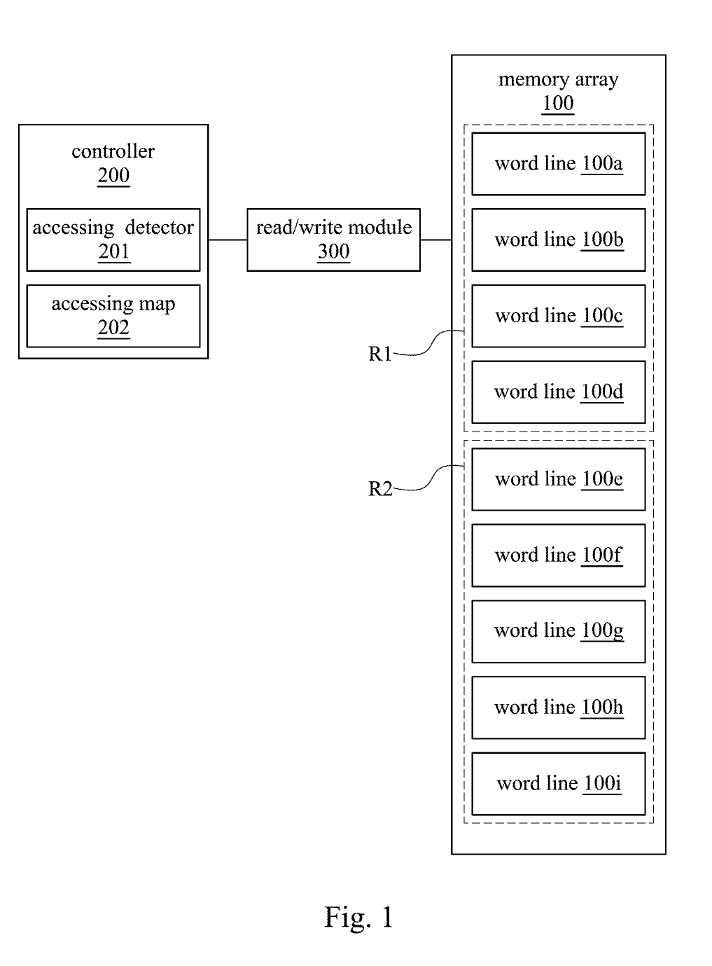

FIG. 1 is a schematic diagram of a system for preserving data in a volatile memory according to some embodiments of present disclosure. In the embodiment, a memory array 100 is shown in FIG. 1, wherein the memory array 100 comprises several word lines 100a-100i. The word lines 100a-100e are comprised by a first refreshing unit R1, wherein the first refreshing unit R1 is provided to refresh data stored in the word lines 100a-100e according to a first cycle. The word lines 100f-100i are comprised by a second refreshing unit R2, wherein the second refreshing unit R2 is provided to refresh data stored in the word lines 100f-100i according to a second cycle. In this embodiment, the word lines 100a-100i are rows stored with data but the word lines 100f-100i are unused word lines.

As shown in FIG. 1, in the embodiment, the memory array 100 is electrically connected to a controller 200 via a read/write module 300. The controller 200 may access the word lines 100a-100i in the memory array 100 through the read/write module 300. The controller 200 shown in FIG. 1 comprises an accessing detector 201 and stored with an accessing map 202. The accessing map 202 is a map representing relationships between logical addresses and physical addresses. Each of the word lines 100a-100i is assigned with a physical address, and the physical address is linked to a logical address. The controller 200 may access data stored in a specific word line based on logical addresses. According to the accessing map 202, when a logical address is input to the controller 200, the controller 200 may locate a physical address corresponding to the logical address and access data stored in the word line directed by the physical address via the read/write module 300.

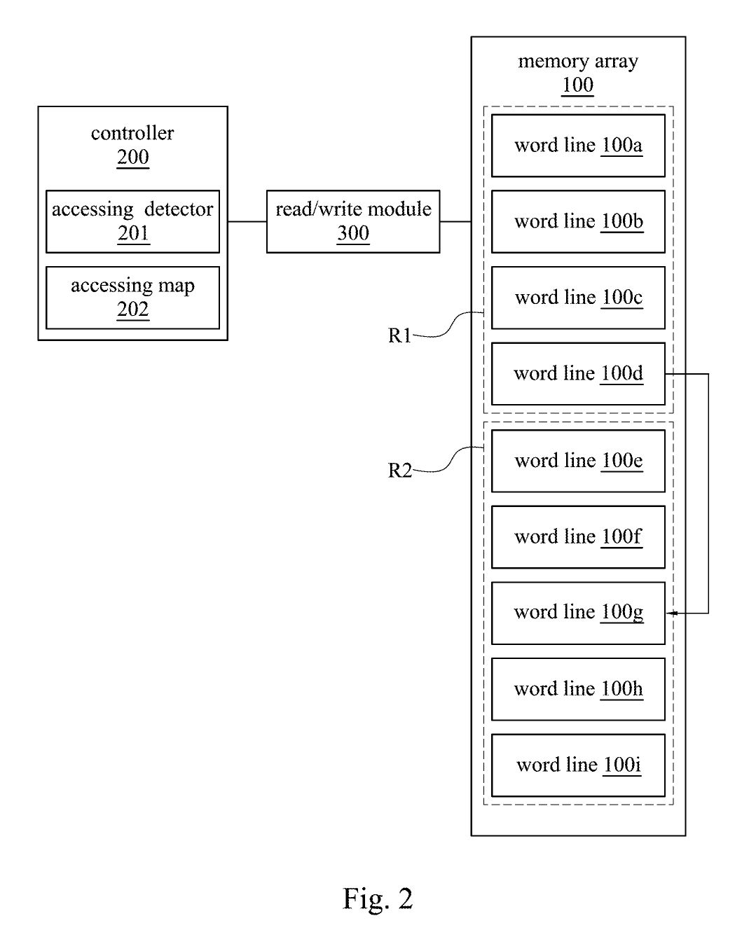

FIG. 2 is a schematic diagram of a system for preserving data in a volatile memory according to the embodiment of FIG. 1. In the embodiment, the accessing detector 201 is configured to detect a row-hammer indication. The row-hammer indication is to indicate whether a first word line is frequently accessed. The row-hammer indication may trigger the accessing detector 201 to copy data stored in a word line to another word line in the memory array 100. Another word line that the data is copied thereto was an unused word line. In some embodiment, another word line that the data is copied thereto is adjacent to at least one unused word line. For example, when the accessing detector 201 is triggered to copy data stored in a first word line to a second word line, the physical address of the second word line may be linked to the logical address corresponding the first word line. The relationship may be stored to the accessing map 202. After the relationship is built, the logical address directing to the data includes two physical addresses corresponding to the first and second word lines, respectively. It is to say, when the controller 200 is going to access the data, both the first and second word lines are available to be selectively accessed when the logical address is directed.

In the embodiment, the accessing detector 201 is configured to detect a row-hammer indication with respect to the word lines 100a-100i. The row-hammer indication is determined by counting a number of each of the word lines 100a-100i has been accessed. The row-hammer indication may trigger the accessing detector 201 to copy data when the number exceeds a threshold. In the embodiment, the word line 100d is a hot row, which means data stored in the word line 100d is frequently accessed within the first cycle. The accessing detector 201 may continuously count a number of word line 100d being accessed. When the number of the word line 100d being accessed exceeds the threshold, the accessing detector 201 is triggered to copy the data stored in the word line 100d to the word line 100g.

In the embodiment, the physical address of the word line 100g may be linked with the logical address corresponding to the word line 100d, therefore, the logical address corresponding to the word line 100d are now directed to both the word line 100d and the word line 100g. The relationship may be stored in the accessing map 202. It can be seen that the word line 100g was an unused word line before the data is copied thereto, and the word line 100f and the word line 100h adjacent to the word line 100g are both unused word lines as well. However, it should be understood that the embodiment is only an example of present disclosure, the word lines being used to store the data may not be limited to the word line 100d and the word line 100g, other word lines in the memory array 100 are also applicable.

Afterwards, when the controller 200 tries to access the data, the logical address being located may direct to both the word line 100d and the word line 100g, then the controller 200 may accesses the data from the word line 100d and the word line 100g by turns. As such, there are two word lines stored with the frequently used data after the row-hammer indication is detected, so the frequency for a hot row being accessed in a high frequency may be relieved. Furthermore, the word line 100g is adjacent to two unused word lines so that data corruptions happening on the word lines adjacent to the word line 100g may be prevented.

As shown in FIG. 1, in the embodiment, the accessing detector 201 is triggered by the row-hammer indication to copy the data from the word line 100d to the word line 100g. The physical address of the word line 100g is linked with the logical address corresponding to the word line 100d in the accessing map 202. As mentioned, the first refreshing unit R1 is refreshed according to the first cycle. Once the first refreshing unit R1 is refreshed, all the word lines 100a-100e belongs to the first refreshing unit R1 are refreshed. However, in some embodiments, when the first refreshing unit R1 is refreshed, the accessing detector 201 is further configured to discard the data stored in the word line 100d. When the data stored in the word line 100d is discarded by the accessing detector 201, the physical address of the word line 100d may be unlinked from the logical address directed to the data. It is to say, after the data stored in the word line 100d is discarded, only the physical address of the word line 100g can be referenced from the logical address directed to the data.

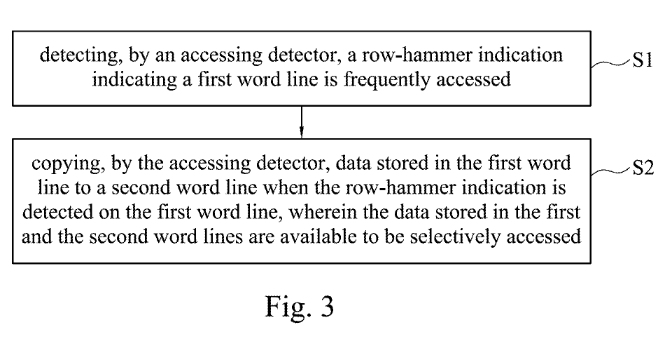

FIG. 3 is a flow chart of a method for preserving data in a volatile memory according to some embodiments of present disclosure. The configuration of the volatile memory may be referenced to the embodiment shown in FIG. 1 and FIG. 2. The steps of the method will be listed and explained in detail in following segments.

Step S1: detecting, by an accessing detector, a row-hammer indication indicating a first word line is frequently accessed. As shown in the embodiments of FIG. 1 and FIG. 2, the accessing detector 201 is configured to detect the word lines 100a-100i in the memory array 100. In the embodiment, the row-hammer indication is determined by counting a number of each of the word lines 100a-100i has been accessed. When the number of one of the word lines 100a-100i exceeds a threshold, the row-hammer indication is detected by the accessing detector 201.

Step S2: copying, by the accessing detector, data stored in the first word line to a second word line when the row-hammer indication is detected on the first word line, wherein the data stored in the first and the second word lines are available to be selectively accessed. As shown in the embodiments of FIG. 1 and FIG. 2, the accessing detector 201 detects the row-hammer indication from the word line 100d, and the accessing detector 201 copies the data stored in the word line 100d to the word line 100g. The word line 100g was an unused word line before the data is copied thereto. The word line 100f and the word line 100h adjacent to the word line 100g that the data is copied thereto are both unused word lines. The physical address of the word line 100g may be linked with the logical address corresponding to the word line 100d, and the relationship may be stored in the accessing map 202. As such, when the accessing detector 201 is going to access the data, the logical address corresponding to the data may direct to the word line 100d to the word line 100g, so the accessing detector 201 may selectively access the data from the word line 100d and the word line 100g via the read/write module 300. Therefore, the row-hammer side effect on the word lines 100a-100i may be reduced.

As described, present disclosure provides an approach to make specific parts of a virtual object being concealed according to the biometric characteristics of users. The method makes portions of the virtual object not being disclosed to some users without enough permission levels, provides a solid solution for establishing information security in the simulated environment.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

1. A system for preserving data in a volatile memory, wherein the volatile memory comprises a plurality of word lines for storing data, wherein the system comprising:
a controller circuit, configured to detect a row-hammer indication indicating a first word line is frequently accessed, wherein the accessing detector copies data stored in the first word line to a second word line when the row-hammer indication is detected on the first word line, wherein the data stored in the first and the second word lines are available to be selectively accessed,
wherein the first word line belongs to a first refreshing unit of the volatile memory and the second word line belongs to a second refreshing unit of the volatile memory,
wherein the first refreshing unit and the second refreshing unit have different refresh cycles,
wherein the controller circuit is further configured to discard the data stored in the first word line when the first refreshing unit is refreshed.

2. The system of claim 1, wherein the row-hammer indication is determined by counting a number of times the first word line has been accessed, and wherein the row-hammer indication is detected when the number exceeds a threshold.

3. The system of claim 1, wherein the data stored in the first and the second word lines are accessed by turns.

4. The system of claim 1, wherein the second word line is an unused word line.

5. The system of claim 4, wherein the second word line is adjacent to at least one unused word line.

6. The system of claim 1, wherein the second word line is linked to a logical address corresponding to the first word line.

7. (canceled)

8. (canceled)

9. The system of claim 1, wherein the first word line is unlinked from the logical address when the data stored in the first word line is discarded.

10. A method for preserving data in a volatile memory, wherein the volatile memory comprises a plurality of word lines for storing data, wherein the method comprises:
detecting, by an accessing detector, a row-hammer indication indicating a first word line is frequently accessed; and
copying, by the accessing detector, data stored in the first word line to a second word line when the row-hammer indication is detected on the first word line, wherein the data stored in the first and the second word lines are available to be selectively accessed,
discarding, by the accessing detector, the data stored in the first word line when the first refreshing unit is refreshed,
wherein the first word line belongs to a first refreshing unit of the volatile memory and the second word line belongs to a second refreshing unit of the volatile memory,
wherein the first refreshing unit and the second refreshing unit have different refresh cycles.

11. The method of claim 10, wherein the row-hammer indication is determined by counting a number of times the first word line has been accessed, and wherein the row-hammer indication is detected when the number exceeds a threshold.

12. The method of claim 10, wherein the data stored in the first and the second word lines are accessed by turns.

13. The method of claim 10, wherein the second word line is an unused word line.

14. The method of claim 13, wherein the second word line is adjacent to at least one unused word line.

15. The method of claim 10, further comprising:
linking, by the accessing detector, the second word line to a logical address corresponding to the first word line.

16. (canceled)

17. (canceled)

18. The method of claim 10, further comprising:
unlinking, by the accessing detector, the first word line from the logical address when the data stored in the first word line is discarded.
